(19) United States
(12) Patent Application Publication
(10) Pub. No.: US 2015/0073735 A1
(43) Pub. Date: Mar. 12, 2015

(54) METHOD FOR ADAPTIVE FAULT LOCATION IN POWER SYSTEM NETWORKS

(71) Applicant: King Fahd University Of Petroleum And Minerals, Dhahran (SA)

(72) Inventors: MOHAMED ALI YOUSEF ABIDO, DHAHRAN (SA); ALI HASSAN AL-MOHAMMED, DHAHRAN (SA)

(73) Assignee: King Fahd University Of Petroleum And Minerals, Dhahran (SA)

(21) Appl. No.: 14/024,551

(22) Filed: Sep. 11, 2013

(51) Int. Cl. G01R 31/08

(52) U.S. Cl. CPC G01R 31/08
USPC 702/59

(57) ABSTRACT

The adaptive fault location method for power system networks utilizes phasor measurement units (PMUs) disposed at disparate locations to obtain synchronized phasor measurements. Three different sets of pre-fault voltage and current phasor measurements are obtained at both terminals of the line under test. The three sets of local PMU measurements at each terminal are used for online calculation of a corresponding system's Thevenin equivalent (TE). This representation of the power system pre-fault network is a reduced two-terminal equivalent. Using the method of multiple measurements with linear regression (MMLR), the three sets of PMU measurements are also employed for online calculation of the transmission line parameters (series resistance, series reactance and shunt susceptance). Online determination of the TEs and line parameters can enhance fault location accuracy by avoiding possible mismatch with the actual parameters due to system loading and other environmental conditions.

### BACKGROUND OF THE INVENTION

1. Field of the Invention

The present invention relates to fault location, and particularly to an adaptive fault location method for power system networks.

2. Description of the Related Art

Accurate and swift fault location on a power network can expedite repair of faulted components, speed-up power restoration and thus enhance power system reliability and availability. Furthermore, rapid restoration of service can reduce customer complaints, outage time, loss of revenue and crew repair expenses.

A phasor measurement unit (PMU) or synchrophasor is a device which measures the electrical waves on an electricity grid, using a common time source for synchronization. Time synchronization allows synchronized real-time measurements of multiple remote measurement points on the grid. In power engineering, these are also commonly referred to as synchrophasors and are considered one of the most important measuring devices in the future of power systems. A PMU can be a dedicated device, or the PMU function can be incorporated into a protective relay or other device. A PMU can measure 50/60 hertz (Hz) alternating current (AC) waveforms (voltages and currents) typically at a rate of 48 samples per cycle (2880 samples per second), for example. The analog AC waveforms can be digitized by an Analog to Digital converter for each phase. A phase-lock oscillator along with a Global Positioning System (GPS) reference source can provide synchronized sampling with 1 microsecond accuracy. The resultant time tagged phasors can be transmitted to a local or remote receiver, such as at rates up to 60 samples per second.

A phasor is a complex number that represents both the magnitude and phase angle of the sine waves found in electricity. Phasor measurements that occur at the same time are called “synchrophasors”, as are the PMU devices that allow their measurement. In typical applications phasor measurement units are sampled from widely dispersed locations in the power system network and synchronized from the common time source of a global positioning system (GPS) radio clock. Synchrophasor technology provides a tool for system operators and planners to measure the state of the electrical system and manage power quality.

Synchrophasors can be used to measure voltages and currents at principal intersecting locations (critical substations) on a power grid and can output relatively accurate time-stamped voltage and current phasors. Because these phasors are truly synchronized, a synchronized comparison of two quantities is possible, in real time. These comparisons can be used to assess system conditions, such as; frequency changes, megawatts (MW), megavolt-ampere reactive (MVAR), kilovolts (kV), kiloamperes (kA) etc. The monitored points are preselected through various studies to make relatively accurate phase angle measurements to indicate shifts in system (grid) stability. The phasor data can be collected either on-site or at centralized locations, such as by using Phasor Data Concentrator technologies. The data can then be transmitted to a regional monitoring system, such as the local Independent System Operator (ISO). These ISO's can monitor phasor data from individual PMU's or from a plurality of PMU's, such as to establish controls for power flow from multiple energy generation sources (nuclear, coal, wind, etc.).

Recent advancements in these GPS synchronized Phasor Measurement Units (PMUs) have enabled their use in the field of fault location. Recognizing the importance of the fault location function for electric power utilities, several PMU-based fault location algorithms have been proposed. Some of these are based on using both synchronized current and voltage phasors at the two ends of a line. Other algorithms are developed based on utilizing only voltage phasor measurements to avoid the consequences of inappropriate operation of current transformers due to an overvoltage and a transient state of a power network during a fault period.

Various fault detection and/or location algorithms exist that can consider arcing faults, fault location schemes for aged power cables, two-terminal and three-terminal transmission lines, double-circuit transmission lines, overhead line combined with an underground power cable and transposed/untransposed transmission lines. To determine the fault location, these classical algorithms typically need the line impedance parameters and the system Thevenin equivalents (TEs) at the line terminals to be known. Such parameters are assumed to be provided by the electric utility.

To improve the fault location accuracy of the typical PMU-based fault location algorithms, various adaptive fault location algorithms have been developed. The idea of adaptive fault location on transmission lines boils down to proper estimation of line parameters and system impedance. Various adaptive fault location algorithms either utilize voltage and current phasor measurements at both ends of a line for online calculation of the transmission line parameters or do not require the line parameters at all. These algorithms, however, still require the system TEs at the line terminals to be provided by the electric utility. It would be advantageous in fault location in power systems to reduce a need that system TEs be supplied by the electric utility.

Thus, an adaptive fault location method for power system networks addressing the aforementioned problems is desired.

### SUMMARY OF THE INVENTION

Embodiments of methods for adaptive fault location in power system networks are based on synchronized phasor measurements obtained by using Phasor Measurement Units (PMUs). To enhance accuracy, the measurements are generated independent of any data provided by the electric utility. The adaptive fault location method for power system networks uses three different sets of pre-fault voltage and current phasor measurements at both terminals of the faulty line obtained through the PMUs. The three sets of local PMU measurements at each terminal can be used for online calculation of the corresponding Thevenin's equivalent (TE). The transmission line parameters are calculated online by applying the method of multiple measurements with linear regression (MMLR) to the three sets of PMU measurements. Online determination of the TEs and line parameters can avoid possible mismatch with the actual parameters due to system loading and other environmental conditions. The adaptive fault location method for power system networks can be applied to any power system such as a 115 kV system from a Saudi Electricity Company (SEC) network, for example. The simulation results implementing methods for adaptive fault location in power system networks obtained using PSCAD/EMTDC and MATLAB simulation tools for power systems indicate that the results are relatively highly accurate and independent of fault type, fault location, fault resistance, fault inception angle and pre-fault loading.

These and other features of the present invention will become readily apparent upon further review of the following specification and drawings.

### BRIEF DESCRIPTION OF THE DRAWINGS

FIG. 1 is a graph illustrating a phasor representation of a sinusoidal waveform.

FIG. 2A is a π-type equivalent circuit of a single line.

FIG. 2B is a superimposed network of a transmission line.

FIG. 3 is a generalized system for implementing embodiments of methods for adaptive fault location in power system networks according to the present invention.

FIG. 4 is a flow chart illustrating embodiments of methods for adaptive fault location in power system networks according to the present invention.

FIG. 5 is a one line diagram of 115 kV SEC system in which embodiments of methods for adaptive fault location in power system networks can be utilized to determine fault locations according to the present invention.

FIG. 6 is a graph illustrating a Thevenin impedance at terminal A (bus-38) for adaptive fault location determination in the system of FIG. 5 according to the present invention.

FIG. 7 is a graph illustrating a Thevenin impedance at terminal B (bus-30) for adaptive fault location determination in the system of FIG. 5 according to the present invention.

FIG. 8 is a graph illustrating sampling of voltage and current signals for adaptive fault location determination at terminals A and B in a power system.

FIG. 9 is a chart showing the effect of fault type on fault location accuracy according to the present invention.

FIG. 10 is a graph showing fault location accuracy for a fault type AG according to the present invention.

FIG. 11 is a graph showing fault location accuracy for a fault type BC according to the present invention.

FIG. 12 is a graph showing fault location accuracy for a fault type CAG according to the present invention.

FIG. 13 is a graph showing fault location accuracy for a fault type ABC according to the present invention.

FIG. 14 is a graph showing fault location error versus fault resistance for a fault type AG according to the present invention.

FIG. 15 is a graph showing fault location error versus fault resistance for a fault type BC according to the present invention.

FIG. 16 is a graph showing fault location error versus fault resistance for a fault type CAG according to the present invention.

FIG. 17 is a graph showing fault location error versus fault resistance for a fault type ABC according to the present invention.

FIG. 18 is a graph showing fault location error versus fault inception angle for fault types AG, BC and CAG according to the present invention.

Unless otherwise indicated, similar reference characters denote corresponding features consistently throughout the attached drawings.

### DETAILED DESCRIPTION OF THE PREFERRED EMBODIMENTS

Embodiments of methods for adaptive fault location method in power system networks use measurements obtained from phasor measurement units (PMUs). FIG. 1 shows a signal 100 represented as a steady-state waveform 102 of a nominal power frequency signal and its equivalent phasor 104. If the waveform observation starts at the instant t=0, the steady-state waveform can be represented by a complex number with a magnitude equal to the root-mean-square (rms) value of the signal and with a phase angle equal to the angle a. In a digital measuring system, samples of the waveform for one (nominal) period are collected, starting at t=0, and then the fundamental frequency component of the Discrete Fourier Transform (DFT) is calculated according to the relation:

$$X = \frac{\sqrt{2}}{N} {\sum }_{k = 1}^{N} {x}_{k} {e}^{- j 2 π k / N} \qquad ( 1 )$$

where N is the total number of samples in one period, X is the phasor, and xₖ is the waveform samples. Advantages of this definition of the phasor include that it uses a number of samples N of the waveform, and consequently can be an accurate representation of the fundamental frequency component when other transient components are present. Once the phasors (Xₐ, X_{b}, and X_{c}) for the three phases are computed, positive, negative and zero sequence phasors can be obtained using the following transformation:

$$[ \begin{matrix}{X}_{1} \\ {X}_{2} \\ {X}_{0}\end{matrix} ] = \frac{1}{3} [ \begin{matrix}1 & {e}^{j 2 π / 3} & {e}^{j 4 π / 3} \\ 1 & {e}^{j 4 π / 3} & {e}^{j 2 π / 3} \\ 1 & 1 & 1\end{matrix} ] \cdot [ \begin{matrix}{X}_{a} \\ {X}_{b} \\ {X}_{c}\end{matrix} ] \qquad ( 2 )$$

When several voltages and currents in a power system are measured and converted to phasors in this fashion, they are on a common reference if they are sampled at precisely the same instant. This can be achieved in a substation, where the common sampling clock pulses can be distributed to all the measuring systems. However, to measure common-reference phasors in substations separated from each other by long distances, the task of synchronizing the sampling clocks is not a trivial one. Only with the advent of the Global Positioning System (GPS) satellite transmissions, the PMU technology has now reached a stage whereby synchronization of the sampling processes in distant substations are achieved economically and with an error of less than 1 microsecond (μs). This error corresponds to approximately 0.021° for a 60 Hz system and 0.018° for a 50 Hz system, for example, and indicates a relatively good accuracy. In this regard, synchronization signals from satellite transmissions of a global positioning system (GPS) can be used to synchronize the acquisition of pre-fault and the post-fault phasor measurements used in adaptive fault location in embodiments of methods for adaptive fault location in power system networks.

Adaptive fault location in embodiments of methods for adaptive fault location in power system networks use local PMU measurements to determine online systems Thevenin Equivalents (TEs) at the terminals of the line. This is possible with PMUs because voltage and current phasors are provided at high rates of one measurement per cycle, which typically is not possible with the conventional supervisory control and data acquisition (SCADA) systems because these SCADA systems are relatively slow and generally cannot handle the relatively high rates. Three consecutive voltage and current (V,I) measurements can be used to determine an exact TE at the two line terminals. It is essential to have the three sets of phasor measurements refer to the same reference. From the first and second sets of voltage and current measurements, the following equation can be written:

$${( r + \frac{{P}_{1} - {P}_{2}}{{I}_{2}^{2} - {I}_{2}^{2}} )}^{2} + {( x - \frac{{Q}_{1} - {Q}_{2}}{{I}_{1}^{2} - {I}_{2}^{2}} )}^{2} = \frac{{V}_{2}^{2} - {V}_{1}^{2}}{{I}_{1}^{2} - {I}_{2}^{2}} + {( \frac{{P}_{1} - {P}_{2}}{{I}_{1}^{2} - {I}_{2}^{2}} )}^{2} + {( \frac{{Q}_{1} - {Q}_{2}}{{I}_{1}^{2} - {I}_{2}^{2}} )}^{2} \qquad ( 3 )$$

where r and x are the resistance and the reactance, respectively, of the Thevenin impedance (Zₜₕ). P and Q are the real and reactive powers, respectively. Equation (3) represents a circle in the impedance plane defining the locus for the Zₜₕ that satisfies the two measurements but it does not define a specific value for the Zₜₕ. Therefore, a third measurement is required which can be used with either the first or the second measurement in the same way to produce another circle. The intersection of the two circles is the equivalent Zₜₕ. The coordinates of the intersection point in the Z-plane define the values of the resistance and reactance of the Zₜₕ. The equivalent Thevenin voltage (Eₜₕ) at a node is found knowing the Zₜₕ and the local V and I measurements at that node as described by:

V=Eₜₕ+Zₜₕ·I (4)

Aspects of the adaptive fault location in embodiments of methods for adaptive fault location in power system networks typically can involve online determination of series resistance, series reactance and shunt admittance of the line under test. PMUs can be utilized for online measurements of transmission line parameters. Both positive and zero sequence impedance parameters are calculated based on voltage and current phasor measurements obtained by PMUs installed at both ends of the transmission line. Even though various forms of PMU-based techniques for computing transmission line parameters exist, such as Iterative methods, a least-square approach and the non-linear optimal estimation theory to determine the series resistance, series reactance and shunt susceptance per unit length of a transmission line, embodiments of methods for adaptive fault location in power system networks typically utilize MMLR due to its relatively acceptable performance in the presence of both measurements' random noise and bias errors, for example.

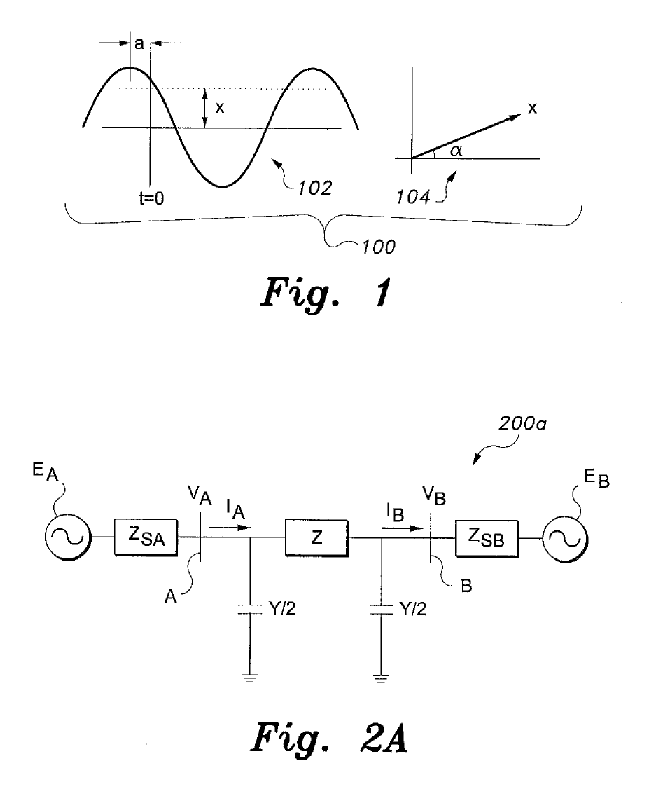

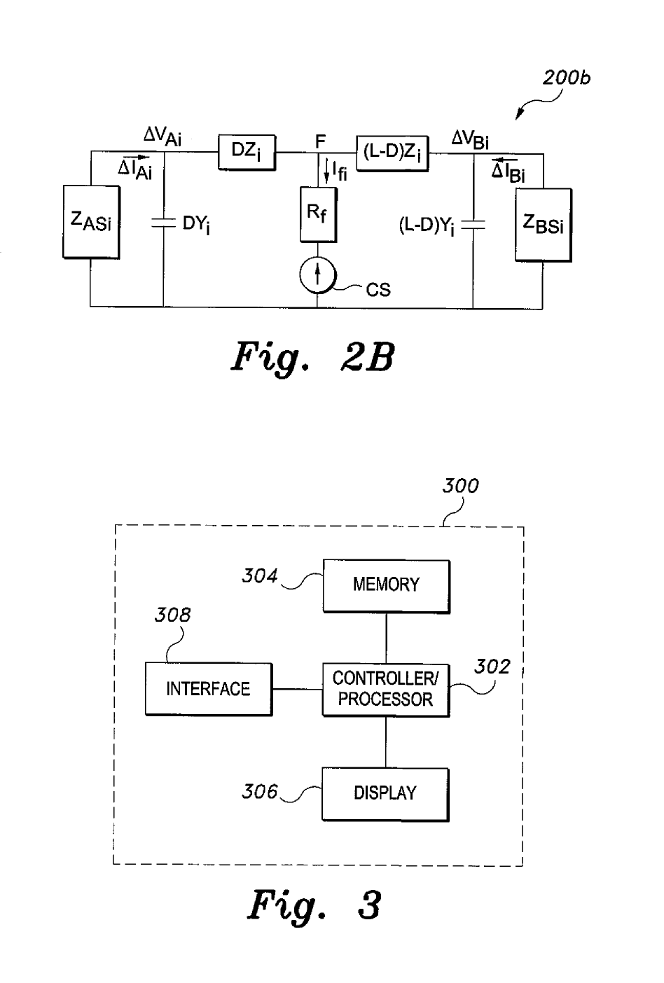

As shown in FIG. 2A, a single line with its π-type equivalent circuit 200a is represented during normal operation where V_{A} and V_{B} are the Phase voltages at bus A and bus B, respectively, I_{A} and I_{B} are the Phase currents at bus A and bus B, respectively, Z is the Line impedance, Y is the Line admittance, Z_{SA} and Z_{SB} are the System's Thevenin impedances at bus A and bus B, respectively, and E_{A} and E_{B} are the System's Thevenin voltages at bus A and bus B, respectively.

The two-port ABCD parameters are used to represent the transmission line in the most general form. If three measurements are collected from the PMUs, the following relations can be defined:

$$\begin{matrix}E = [ \begin{matrix}Re [ {V}_{A 1} ] \\ Im [ {V}_{A 1} ] \\ Re [ {V}_{A 2} ] \\ Im [ {V}_{A 2} ] \\ Re [ {V}_{A 3} ] \\ Im [ {V}_{A 3} ]\end{matrix} ] & ( 5 ) \\ H = [ \begin{matrix}Re [ {V}_{B 1} ] & - Im [ {V}_{B 1} ] & Re [ {I}_{B 1} ] & - Im [ {I}_{B 1} ] \\ Im [ {V}_{B 1} ] & Re [ {V}_{B 1} ] & Im [ {I}_{B 1} ] & Re [ {I}_{B 1} ] \\ Re [ {V}_{B 2} ] & - Im [ {V}_{B 2} ] & Re [ {I}_{B 2} ] & - Im [ {I}_{B 2} ] \\ Im [ {V}_{B 2} ] & Re [ {V}_{B 2} ] & Im [ {I}_{B 2} ] & Re [ {I}_{B 2} ] \\ Re [ {V}_{B 3} ] & - Im [ {V}_{B 3} ] & Re [ {I}_{B 3} ] & - Im [ {I}_{B 3} ] \\ Im [ {V}_{B 3} ] & Re [ {V}_{B 3} ] & Im [ {I}_{B 3} ] & Re [ {I}_{B 3} ]\end{matrix} ] & ( 6 ) \\ F = [ \begin{matrix}Re [ A ] \\ Im [ A ] \\ Re [ B ] \\ Im [ B ]\end{matrix} ] & ( 7 )\end{matrix}$$

Using equations (5), (6) and (7), the real and imaginary parts of a specified phasor are represented using Re[.] and Im[.], respectively, and the subscripts 1, 2 and 3 denote the measurement set number. Utilizing the unbiased least square estimator, the best estimation of the chain parameters A and B are found to be:

F=(H^{T}H)⁻¹H^{T}E (8)

Similarly, best estimated values of C and D can be found. The impedance parameters are calculated using equations (9) and (10),

$$\begin{matrix}Z = B & ( 9 ) \\ Y = \frac{2 \cdot ( A - 1 )}{B} & ( 10 )\end{matrix}$$

Once the system TEs at the line terminals and the line parameters are determined, the principle of superposition can be applied in the linear network theory to separate the post-fault network into a pre-fault network and a superimposed network. An embodiment of the adaptive fault location method for power system networks utilizes the most recent set of measurements out of the aforementioned three sets of pre-fault PMU measurements. Superimposed electrical measurements are used in the adaptive fault location method to reduce the effect of pre-fault load current on location accuracy. Also, the pre and post-fault phasor measurement acquisition can include obtaining the phasor measurements from Phasor Measurement Units (PMUs) in operable communication with first and second terminals of a power system network, for example.

As shown in FIG. 2B, the superimposed phase network is transformed into a sequence electrical measurement network 200b, where i is the i^{th} sequence, and i=0,1,2, corresponding to a zero, a positive and a negative sequence, and CS is a current source. Furthermore, ΔV_{Ai} is the i^{th} sequence of superimposed voltage at A, ΔV_{Bt} is the i^{th} sequence of superimposed voltage at B, ΔI_{Ai} is the i^{th} sequence of superimposed current at A, and ΔI_{Bi} is the i^{th} sequence of superimposed current at B. Also shown in FIG. 2B, Zᵢ is the i^{th} sequence impedance of the line between terminals A and B, and Yᵢ is the i^{th} sequence admittance of the line between terminals A and B. Moreover, R_{f} is the fault resistance, I_{fi} is th i^{th} sequence of fault current, Z_{ASi} is the i^{th} sequence of terminal A equivalent source impedance, Z_{Bsi} is the i^{th} sequence of terminal B equivalent source impedance, L is the total length of a transmission line between terminals A and B, and D is the distance between bus A and fault point F (or D can be determined to be the distance between bus B and the fault point F).

The equivalent source impedances are changed according to the change of a generation mode of the system. Furthermore, the source impedances are calculated online so that the electrical measurements used in the fault location equation can reflect the practical operation mode. With respect to FIG. 2B, the sequence source impedances are calculated as:

$$\begin{matrix}{Z}_{ASi} = \frac{Δ {V}_{Ai}}{Δ {I}_{Ai}} & ( 11 ) \\ {Z}_{BSi} = \frac{Δ {V}_{Bi}}{Δ {I}_{Bi}} & ( 12 )\end{matrix}$$

The sequence voltage at the fault resistance, as a fault voltage, can be determined from the changed sequence voltages at bus A and bus B and from the currents flowing in the transmission from bus A and bus B, as described by:

$$\begin{matrix} {V}_{AFi} = ( Δ {I}_{Ai} - Δ {V}_{Ai} {DY}_{i} ) \times ( ( {Z}_{ASi} ‖ \frac{1}{{DY}_{i}} ) + {DZ}_{i} ) & ( 13 ) \\ {V}_{BFi} = ( Δ {I}_{Bi} - Δ {V}_{Bi} ( L - D ) {Y}_{i} ) \times ( ( {Z}_{BSi} ‖ \frac{1}{( L - D ) {Y}_{i}} ) + ( L - D ) {Z}_{i} ) & ( 14 )\end{matrix}$$

Plotting the magnitudes of the first and second fault voltages |V_{AFi}| and |V_{BFi}|, along the entire length of the line L, the point of intersection of the plotted fault voltages determines the fault distance D and the fault location relative to at least one of the terminals A or B. The determined first and second fault voltages from the above relations (13)-(14) can be used for adaptive fault location for various types of faults, such as single line to ground (LG) faults, line to line (LL) faults, line to line to ground (LLG) faults and three phase (LLL) faults.

FIG. 3 illustrates a generalized system 300 for implementing embodiments of apparatuses and methods for an adaptive fault location in power system networks, although it should be understood that the generalized system 300 may represent, for example, a stand-alone computer, computer terminal, portable computing device, networked computer or computer terminal, or networked portable device. Data may be entered into the system 300 by the user or may be received by the system 300 via any suitable type of user or other suitable interface 308, and may be stored in computer readable memory 304, which may be any suitable type of computer readable and programmable memory. Calculations implementing the adaptive fault location determination are performed by the controller/processor 302, which may be any suitable type of computer processor, and may be displayed to the user on the display 306, which may be any suitable type of computer display, for example.

The controller/processor 302 may be associated with, or incorporated into, any suitable type of computing device, for example, a personal computer or a programmable logic controller. The display 306, the controller/processor 302, the memory 304, and any associated computer readable media are in communication with one another by any suitable type of data bus, as is well known in the art.

Examples of computer readable media include a magnetic recording apparatus, non-transitory computer readable storage memory, an optical disk, a magneto-optical disk, and/or a semiconductor memory (for example, RAM, ROM, etc.). Examples of magnetic recording apparatus that may be used in addition to memory 304, or in place of memory 304, include a hard disk device (HDD), a flexible disk (FD), and a magnetic tape (MT). Examples of the optical disk include a DVD (Digital Versatile Disc), a DVD-RAM, a CD-ROM (Compact Disc-Read Only Memory), and a CD-R (Recordable)/RW.

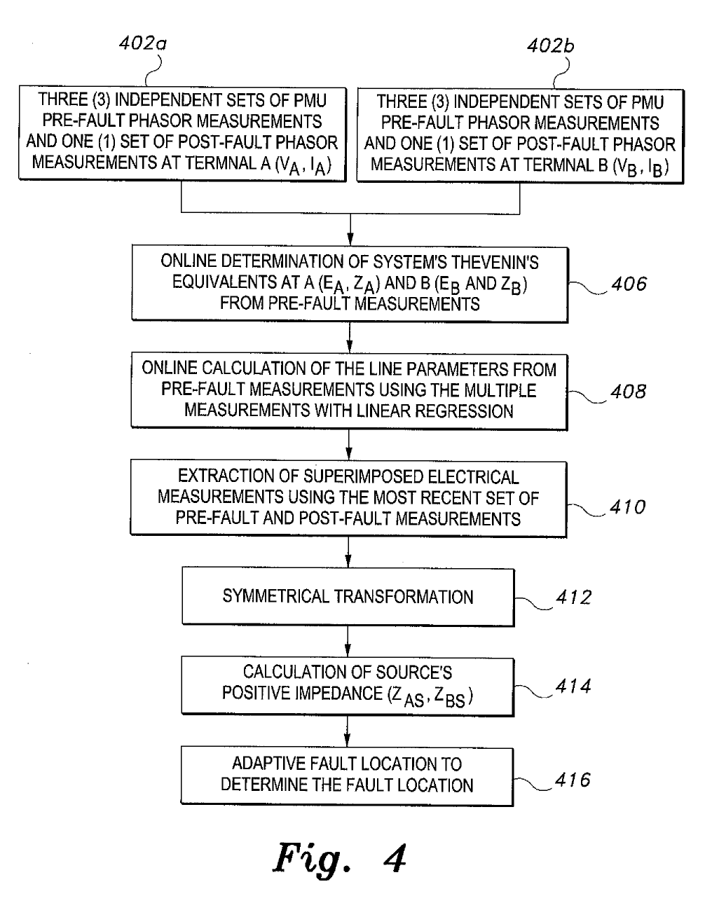

A flow chart of an adaptive fault location algorithm as can be used in implementing embodiments of methods for adaptive fault location in power system networks is shown in FIG. 4, where three independent sets of PMU pre-fault phasor measurements and one set of post-fault phasor measurements are taken at terminals A (V_{A}, I_{A}) and B (V_{B}, I_{B}) at steps 402a and 402b, respectively. Then an online determination at step 406 is made of the system's TE at the terminals A (E_{A}, Z_{A}) and B (E_{B}, Z_{B}) from the pre-fault measurements. Next, an online calculation at step 408 of the line parameters from the pre-fault measurements is made using multiple measurements with linear regression. The superimposed electrical measurements are extracted at step 410 using the line parameters and using the most recent set of pre-fault and post-fault measurements. Following a symmetrical transformation of the electrical measurements to correspond to a sequence network at step 412, a calculation at step 414 of the sources positive impedances are performed based on the transformed electrical measurements. In this manner, using the transformed electrical measurements, the sources positive impedance implemented through equations (11) and (12), and the first and second fault voltages implemented through equations (13) and (14), the intersection of |V_{AFi}| and |V_{BFi}| provides the fault distance D and the fault location is determined at step 416.

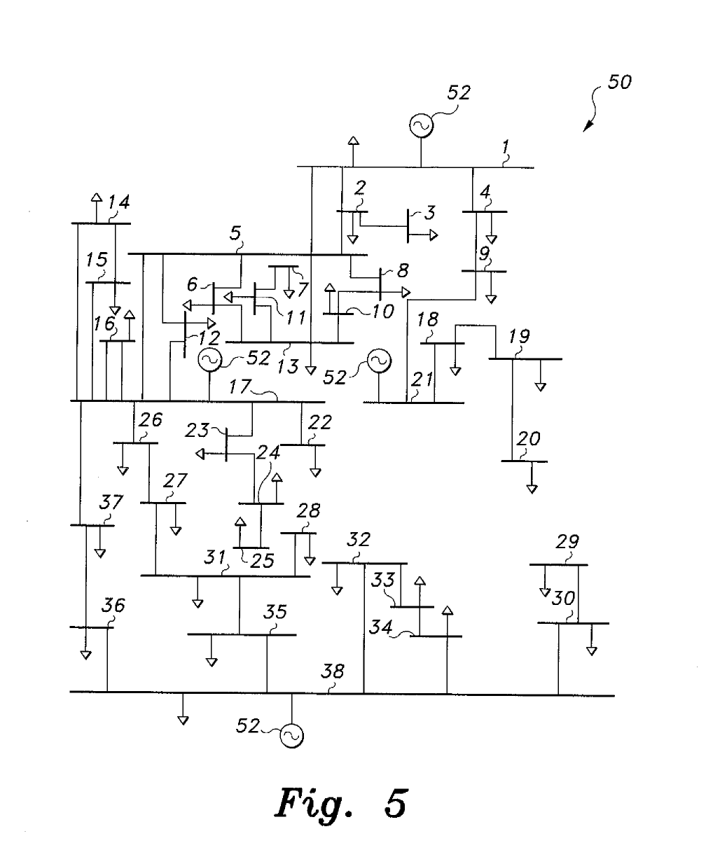

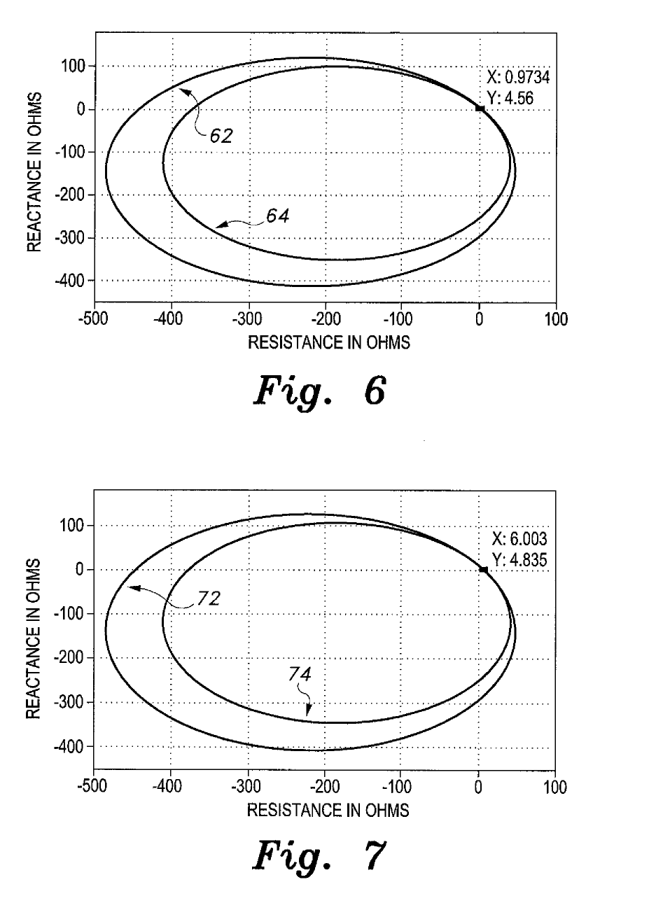

In regards to data generation and conditioning, a 38-bus 115 kV, 60 Hz Saudi Electricity Company-Eastern Operating Area (SEC-EOA) system 50 having buses numbered from 1 through 38 is shown in FIG. 5. Embodiments of methods for adaptive fault location in power system networks are evaluated using pre-fault and post-fault data obtained from reliable PSCAD/EMTDC simulations of faults assumed to occur on the line connecting bus-38, containing terminal A, and bus-30, containing terminal B. The line is modeled by the nominal-π circuit and its parameters are as shown in Table I. The systems Thevenin's impedances at a terminal A and a terminal B are determined as shown in FIG. 6 and FIG. 7, respectively. In reference to FIG. 6, the plot 62 is formed from measurement set (MS)-1 and MS-2, and the plot 64 is formed from MS-2 and MS-3. In reference to FIG. 7, the plot 72 is formed from MS-1 and MS-2, and the plot 74 is formed from MS-2 and MS-3. Thevenin's equivalent voltages are calculated using equation (4) and are shown in Table 1.

TABLE 1
PARAMETERS OF THE 115 KV, 60 HZ NETWORK

| Parameter | Value | |
|---|---|---|
| L | 26 | km |
| Z | 0.014400 + j0.07500 p.u. in 100 MVA Base | |
| Y | 0.012040 p.u. in 100 MVA Base | |
| E_{A} | 112.28 | kV |
| E_{B} | 112.4 | kV |

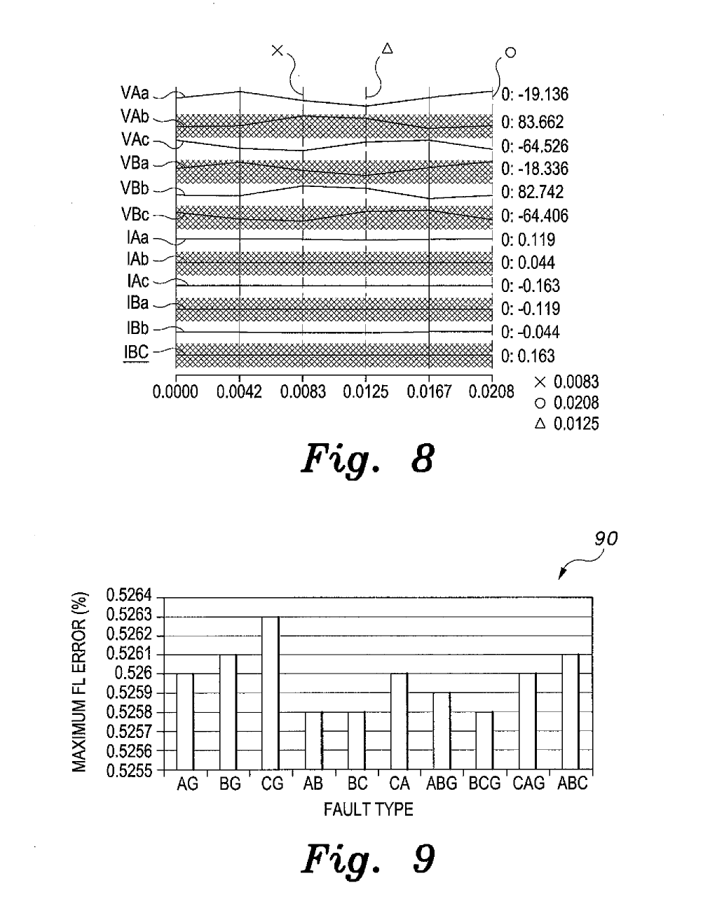

In order to show errors, the current transformers (CTs) and voltage transformers (VTs) located at each line terminal are intentionally assumed as ideal devices. The SEC-EOA 115 kV system 50 of FIG. 5 is analyzed in FIG. 8. The three-phase (a, b, c) voltage and current signals are sampled at a frequency of 240 Hz which corresponds to 4 samples per cycle and are stored for post-processing, and cycle sampling points 0.0042, 0.0083, 0.0125 and 0.0167 are illustrated in FIG. 8. The Discrete Fourier Transform given by equation (1) is applied to extract the voltage and current phasors.

Embodiments of methods for an adaptive fault location in power system networks can be implemented in MATLAB, for example. In order to measure the accuracy of the adaptive fault location, the percentage error can be calculated as:

$$\% Error = \frac{\vert Actual location - Estimated location \vert}{Total line length} \times 100. \qquad ( 15 )$$

To test the accuracy of embodiments of methods for adaptive fault location in power system networks, different fault types, locations and resistances are simulated. Tables 2-5 present the fault location (FL) estimates obtained for single line to ground (LG) faults, line to line (LL) faults, line to line to ground (LLG) faults and three phase (LLL) faults. In these tables, the first, second and third columns show the fault type, fault resistance and actual fault location respectively. The distance to the fault and the errors estimated in an adaptive fault location determination using embodiments of methods for adaptive fault location in power system networks are respectively displayed in the fourth and fifth column of Tables 2-5.

TABLE 2
FAULT-LOCATION ESTIMATES FOR
SINGLE-LINE-TO-GROUND FAULTS

| Fault | Fault | Actual | Estimated | Error of |
|---|---|---|---|---|
| Type | Res. (Ω) | FL (p.u) | FL (p.u) | Estimated FL (%) |
| AG | 10 | 0.2 | 0.2007 | 0.3430 |
| | | 0.4 | 0.3990 | 0.2427 |
| | | 0.6 | 0.5974 | 0.4345 |
| | | 0.8 | 0.7958 | 0.5260 |
| | 100 | 0.2 | 0.2007 | 0.3419 |
| | | 0.4 | 0.3990 | 0.2430 |
| | | 0.6 | 0.5974 | 0.4345 |
| | | 0.8 | 0.7958 | 0.5259 |
| BG | 10 | 0.2 | 0.2007 | 0.3440 |
| | | 0.4 | 0.3990 | 0.2425 |
| | | 0.6 | 0.5974 | 0.4345 |
| | | 0.8 | 0.7958 | 0.5261 |
| | 100 | 0.2 | 0.2007 | 0.3520 |
| | | 0.4 | 0.3990 | 0.2410 |
| | | 0.6 | 0.5974 | 0.4354 |
| | | 0.8 | 0.7958 | 0.5283 |
| CG | 10 | 0.2 | 0.2007 | 0.3451 |
| | | 0.4 | 0.3990 | 0.2422 |
| | | 0.6 | 0.5974 | 0.4346 |
| | | 0.8 | 0.7958 | 0.5263 |
| | 100 | 0.2 | 0.2007 | 0.3616 |
| | | 0.4 | 0.3990 | 0.2395 |
| | | 0.6 | 0.5974 | 0.4365 |
| | | 0.8 | 0.7958 | 0.5305 |

TABLE 3
FAULT-LOCATION ESTIMATES FOR
SINGLE-LINE-TO-LINE FAULTS

| Fault | Fault | Actual | Estimated | Error of |
|---|---|---|---|---|
| Type | Res. (Ω) | FL (p.u) | FL (p.u) | Estimated FL (%) |
| AB | 1 | 0.2 | 0.2007 | 0.3429 |
| | | 0.4 | 0.3990 | 0.2427 |
| | | 0.6 | 0.5974 | 0.4344 |
| | | 0.8 | 0.7958 | 0.5258 |
| | 10 | 0.2 | 0.2007 | 0.3430 |
| | | 0.4 | 0.3990 | 0.2427 |
| | | 0.6 | 0.5974 | 0.4344 |
| | | 0.8 | 0.7958 | 0.5259 |
| BC | 1 | 0.2 | 0.2007 | 0.3433 |
| | | 0.4 | 0.3990 | 0.2425 |
| | | 0.6 | 0.5974 | 0.4344 |
| | | 0.8 | 0.7958 | 0.5258 |
| | 10 | 0.2 | 0.2007 | 0.3441 |
| | | 0.4 | 0.3990 | 0.2424 |
| | | 0.6 | 0.5974 | 0.4345 |
| | | 0.8 | 0.7958 | 0.5260 |
| CA | 1 | 0.2 | 0.2007 | 0.3434 |
| | | 0.4 | 0.3990 | 0.2426 |
| | | 0.6 | 0.5974 | 0.4345 |
| | | 0.8 | 0.7958 | 0.5260 |
| | 10 | 0.2 | 0.2007 | 0.3436 |
| | | 0.4 | 0.3990 | 0.2426 |
| | | 0.6 | 0.5974 | 0.4345 |
| | | 0.8 | 0.7958 | 0.5261 |

TABLE 4
FAULT-LOCATION ESTIMATES FOR
LINE-TO-LINE-TO-GROUND FAULTS

| Fault | Fault | Actual | Estimated | Error of |
|---|---|---|---|---|
| Type | Res. (Ω) | FL (p.u) | FL (p.u) | Estimated FL (%) |
| ABG | 5 | 0.2 | 0.2007 | 0.3429 |
| | | 0.4 | 0.3990 | 0.2427 |
| | | 0.6 | 0.5974 | 0.4344 |
| | | 0.8 | 0.7958 | 0.5259 |
| | 50 | 0.2 | 0.2007 | 0.3429 |
| | | 0.4 | 0.3990 | 0.2427 |
| | | 0.6 | 0.5974 | 0.4344 |
| | | 0.8 | 0.7958 | 0.5259 |
| BCG | 5 | 0.2 | 0.2007 | 0.3433 |
| | | 0.4 | 0.3990 | 0.2426 |
| | | 0.6 | 0.5974 | 0.4344 |
| | | 0.8 | 0.7958 | 0.5258 |
| | 50 | 0.2 | 0.2007 | 0.3433 |
| | | 0.4 | 0.3990 | 0.2426 |
| | | 0.6 | 0.5974 | 0.4344 |
| | | 0.8 | 0.7958 | 0.5258 |
| CAG | 5 | 0.2 | 0.2007 | 0.3433 |
| | | 0.4 | 0.3990 | 0.2426 |
| | | 0.6 | 0.5974 | 0.4345 |
| | | 0.8 | 0.7958 | 0.5260 |
| | 50 | 0.2 | 0.2007 | 0.3433 |
| | | 0.4 | 0.3990 | 0.2426 |
| | | 0.6 | 0.5974 | 0.4345 |
| | | 0.8 | 0.7958 | 0.5260 |

TABLE 5
FAULT-LOCATION ESTIMATES
FOR THREE-PHASE FAULTS

| Fault | Fault | Actual | Estimated | Error of |
|---|---|---|---|---|
| Type | Res. (Ω) | FL (p.u) | FL (p.u) | Estimated FL (%) |
| ABC | 1 | 0.2 | 0.2007 | 0.3432 |
| | | 0.4 | 0.3990 | 0.2426 |
| | | 0.6 | 0.5974 | 0.4344 |
| | | 0.8 | 0.7958 | 0.5259 |
| | 10 | 0.2 | 0.2007 | 0.3440 |
| | | 0.4 | 0.3990 | 0.2425 |
| | | 0.6 | 0.5974 | 0.4345 |
| | | 0.8 | 0.7958 | 0.5261 |

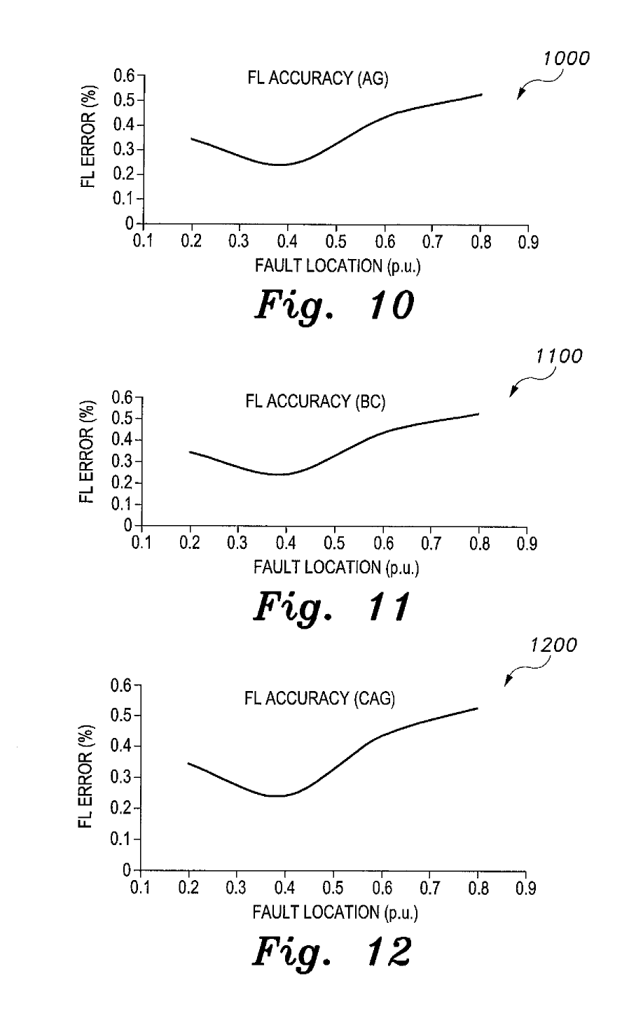

The results obtained from the simulation of embodiments of methods for adaptive fault location in power system networks are depicted in plot 90 of FIG. 9 and plots 1000 through 1300 of FIGS. 10 to 13, respectively. Inspection of the FIGS. 9 to 13 reveals that embodiments of methods for adaptive fault location in power system networks are relatively highly accurate and relatively independent of the fault type and fault location.

Additionally, the impact of the fault resistance variation on the accuracy of adaptive fault location using embodiments of methods for adaptive fault location in power system networks for various types of faults are considered and shown in Tables 6-9. It is assumed that the fault occurs at a distance of 0.8 pu from the bus 38 of FIG. 5. Additionally, the ground faults have been examined for fault resistance values within [0Ω-500Ω]. This represents low-resistance and high-resistance faults. Also, a range of [0Ω-30Ω] for resistance values has been considered for the faults not involving a ground terminal. In all cases, the local and remote source impedances are set as equal to the system values.

TABLE 6
INFLUENCE OF THE FAULT RESISTANCE ON
ACCURACY FORSINGLE-LINE-TO-GROUND FAULTS
(ACTUAL FL: 0.8 P.U.)

| | Fault Type (Estimated = Estim.) | | | | | |
|---|---|---|---|---|---|---|
| | AG | | BG | | CG | |
| | Estim. | Error of | Estim. | Error of | Estim. | Error of |
| Fault Res. | FL | Estim. | FL | Estim. | FL | Estim. |
| (Ω) | (p.u) | FL (%) | (p.u) | FL (%) | (p.u) | FL (%) |
| 0 | 0.7958 | 0.5260 | 0.7958 | 0.5258 | 0.7958 | 0.5258 |
| 1 | 0.7958 | 0.5260 | 0.7958 | 0.5258 | 0.7958 | 0.5259 |
| 5 | 0.7958 | 0.5260 | 0.7958 | 0.5259 | 0.7958 | 0.5261 |
| 10 | 0.7958 | 0.5260 | 0.7958 | 0.5261 | 0.7958 | 0.5263 |
| 20 | 0.7958 | 0.5260 | 0.7958 | 0.5264 | 0.7958 | 0.5268 |
| 50 | 0.7958 | 0.5259 | 0.7958 | 0.5271 | 0.7958 | 0.5282 |
| 100 | 0.7958 | 0.5259 | 0.7958 | 0.5283 | 0.7958 | 0.5305 |
| 200 | 0.7958 | 0.5258 | 0.7958 | 0.5307 | 0.7957 | 0.5352 |
| 400 | 0.7958 | 0.5257 | 0.7957 | 0.5356 | 0.7956 | 0.5446 |
| 500 | 0.7958 | 0.5256 | 0.7957 | 0.5380 | 0.7956 | 0.5493 |

TABLE 7
INFLUENCE OF THE FAULT RESISTANCE ON ACCURACY
FOR LINE-TO-LINE FAULTS (ACTUAL FL: 0.8 P.U.)

| | Fault Type (Estimated = Estim.) | | | | | |
|---|---|---|---|---|---|---|
| | AB | | BC | | CA | |
| | Estim. | Error of | Estim. | Error of | Estim. | Error of |
| Fault Res. | FL | Estim. | FL | Estim. | FL | Estim. |
| (Ω) | (p.u) | FL (%) | (p.u) | FL (%) | (p.u) | FL (%) |
| 0 | 0.7958 | 0.5259 | 0.7958 | 0.5257 | 0.7958 | 0.5260 |
| 0.5 | 0.7958 | 0.5259 | 0.7958 | 0.5258 | 0.7958 | 0.5260 |
| 1 | 0.7958 | 0.5258 | 0.7958 | 0.5258 | 0.7958 | 0.5260 |
| 2.5 | 0.7958 | 0.5258 | 0.7958 | 0.5259 | 0.7958 | 0.5260 |
| 5 | 0.7958 | 0.5259 | 0.7958 | 0.5259 | 0.7958 | 0.5260 |
| 7.5 | 0.7958 | 0.5259 | 0.7958 | 0.5260 | 0.7958 | 0.5261 |
| 10 | 0.7958 | 0.5259 | 0.7958 | 0.5260 | 0.7958 | 0.5261 |
| 15 | 0.7958 | 0.5259 | 0.7958 | 0.5262 | 0.7958 | 0.5261 |
| 20 | 0.7958 | 0.5259 | 0.7958 | 0.5263 | 0.7958 | 0.5262 |
| 30 | 0.7958 | 0.5259 | 0.7958 | 0.5265 | 0.7958 | 0.5263 |

TABLE 8
INFLUENCE OF THE FAULT RESISTANCE
ON ACCURACY FOR LINE-TO-LINE-TO-
GROUND FAULTS (ACTUAL FL: 0.8 P.U.)

| | Fault Type (Estimated = Estim.) | | | | | |
|---|---|---|---|---|---|---|
| | ABG | | BCG | | CAG | |
| | Estim. | Error of | Estim. | Error of | Estim. | Error of |
| Fault Res. | FL | Estim. | FL | Estim. | FL | Estim. |
| (Ω) | (p.u) | FL (%) | (p.u) | FL (%) | (p.u) | FL (%) |
| 0 | 0.7958 | 0.5258 | 0.7958 | 0.5258 | 0.7958 | 0.5260 |
| 1 | 0.7958 | 0.5259 | 0.7958 | 0.5259 | 0.7958 | 0.5260 |
| 5 | 0.7958 | 0.5259 | 0.7958 | 0.5259 | 0.7958 | 0.5260 |
| 10 | 0.7958 | 0.5259 | 0.7958 | 0.5259 | 0.7958 | 0.5260 |
| 25 | 0.7958 | 0.5259 | 0.7958 | 0.5259 | 0.7958 | 0.5260 |
| 50 | 0.7958 | 0.5259 | 0.7958 | 0.5259 | 0.7958 | 0.5260 |
| 100 | 0.7958 | 0.5259 | 0.7958 | 0.5259 | 0.7958 | 0.5260 |
| 150 | 0.7958 | 0.5259 | 0.7958 | 0.5259 | 0.7958 | 0.5260 |
| 200 | 0.7958 | 0.5259 | 0.7958 | 0.5259 | 0.7958 | 0.5260 |
| 250 | 0.7958 | 0.5259 | 0.7958 | 0.5259 | 0.7958 | 0.5260 |

TABLE 9
INFLUENCE OF THE FAULT RESISTANCE ON ACCURACY
FOR THREE-PHASE FAULTS (ACTUAL FL: 0.8 P.U.)

| Fault | Estimated | Error of |
|---|---|---|
| Res. (Ω) | FL (p.u) | Estimated FL (%) |
| 0 | 0.7958 | 0.5259 |
| 0.5 | 0.7958 | 0.5259 |
| 1 | 0.7958 | 0.5259 |
| 2.5 | 0.7958 | 0.5259 |
| 5 | 0.7958 | 0.5259 |
| 7.5 | 0.7958 | 0.5259 |
| 10 | 0.7958 | 0.5260 |
| 15 | 0.7958 | 0.5260 |
| 20 | 0.7958 | 0.5260 |
| 30 | 0.7958 | 0.5261 |

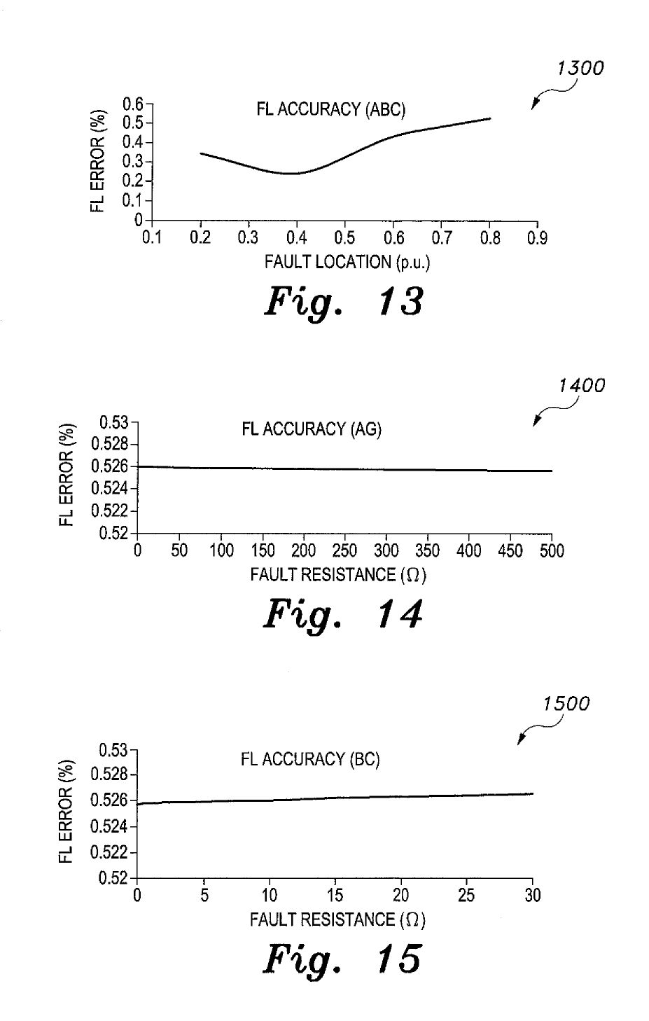

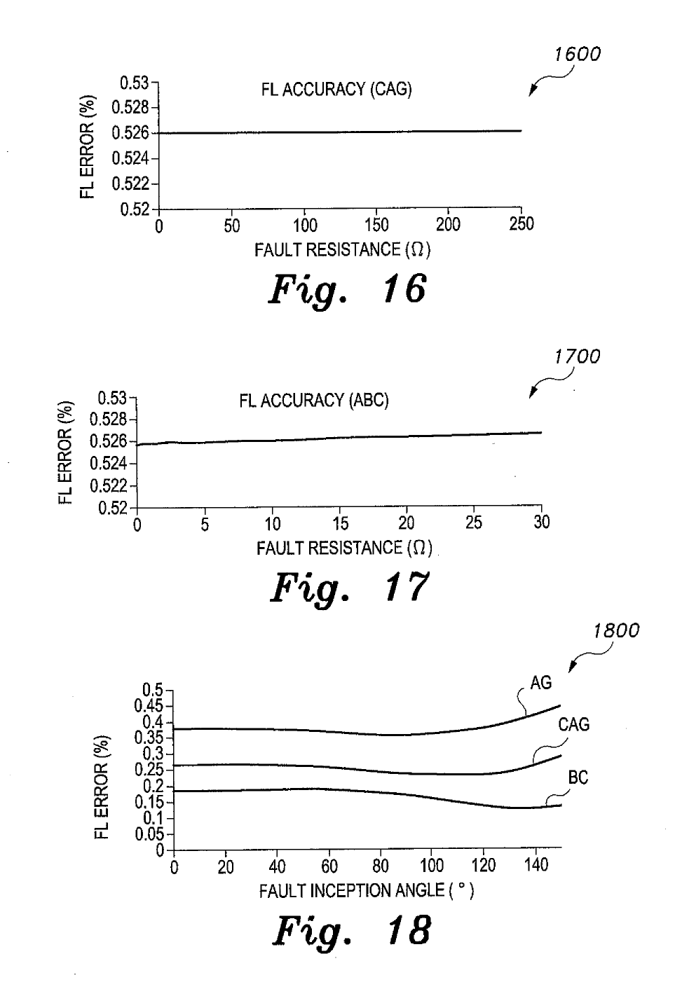

Referring to Tables 6-9, and as depicted in plots 1400 through 1700 of FIGS. 14-17, respectively, it is revealed that highly accurate estimates of the fault location can be successfully achieved using embodiments of methods for adaptive fault location in power system networks. Furthermore, it can be observed that the obtained estimates are relatively robust, being substantially independent of the fault resistance, for example.

In embodiments of methods for adaptive fault location in power system networks, the effect of variation of the fault inception angle on accuracy for faults AG, BC and CAG is shown in Table 10. It is assumed that the fault occurs at a distance of 0.6 p. u. from terminal A. The fault inception angle is varied from 0 to 150°. It can be observed that embodiments of methods for adaptive fault location in power system networks are relatively highly accurate and virtually independent of the fault inception angle with an average error of 0.384%, 0.163% and 0.256% for faults AG, BC and CAG, respectively. Plot 1800 of FIG. 18 depicts the effect of the variation of the fault inception angle on accuracy for the aforementioned types of faults.

TABLE 10
INFLUENCE OF THE FAULT INCEPTION ANGLE ON
ACCURACY (ACTUAL FL: 0.6 P.U.)

| | Fault Type (Estimated = Estim.) | | | | | |
|---|---|---|---|---|---|---|
| | AG | | BC | | BCG | |
| Fault | Estim. | Error of | Estim. | Error of | Estim. | Error of |
| Inception | FL | Estim. | FL | Estim. | FL | Estim. |
| Angle (°) | (p.u) | FL (%) | (p.u) | FL (%) | (p.u) | FL (%) |
| 0 | 0.6023 | 0.3805 | 0.6011 | 0.1851 | 0.6016 | 0.2669 |
| 30 | 0.6023 | 0.3784 | 0.6011 | 0.1873 | 0.6016 | 0.2667 |
| 45 | 0.6022 | 0.3743 | 0.6011 | 0.1890 | 0.6016 | 0.2641 |
| 60 | 0.6022 | 0.3669 | 0.6011 | 0.1876 | 0.6015 | 0.2570 |
| 90 | 0.6021 | 0.3547 | 0.6010 | 0.1679 | 0.6014 | 0.2352 |
| 120 | 0.6023 | 0.3752 | 0.6008 | 0.1330 | 0.6014 | 0.2303 |
| 135 | 0.6024 | 0.4020 | 0.6007 | 0.1218 | 0.6015 | 0.2476 |
| 150 | 0.6026 | 0.4399 | 0.6008 | 0.1294 | 0.6017 | 0.2839 |

Table 11 shows the influence of the pre-fault loading on accuracy for faults AG, BC and CAG using embodiments of methods for adaptive fault location in power system networks. It is assumed that these faults occur at a distance of 0.6 p.u. from terminal A. The pre-fault loading is varied from 0.5 to 3 times its original value. Inspection of Table 11 reveals that embodiments of methods for adaptive fault location in power system networks are relatively highly accurate and generally independent of the pre-fault loading with an average error of 0.492%, 0.296% and 0.378% for the faults AG, BC and CAG, respectively, for example.

TABLE 11
INFLUENCE OF THE PRE-FAULT LOADING AT TERMINAL-A
ON ACCURACY (ACTUAL FL: 0.6 P.U.)

| | Fault Type (Estimated = Estim.) | | | | | |
|---|---|---|---|---|---|---|
| | AG | | BC | | BCG | |
| Variation | | Error | | Error | | Error |
| of Pre- | | of | | of | | of |
| fault | Estim. | Estim. | Estim. | Estim. | Estim. | Estim. |
| Loading | FL | FL | FL | FL | FL | FL |
| (%) | (p.u) | (%) | (p.u) | (%) | (p.u) | (%) |
| −50 | 0.6016 | 0.2691 | 0.6004 | 0.0735 | 0.6009 | 0.1554 |
| −20 | 0.6020 | 0.3359 | 0.6008 | 0.1404 | 0.6013 | 0.2223 |
| 20 | 0.6025 | 0.4250 | 0.6014 | 0.2297 | 0.6019 | 0.3115 |
| 50 | 0.6030 | 0.4918 | 0.6018 | 0.2966 | 0.6023 | 0.3784 |
| 100 | 0.6036 | 0.6029 | 0.6024 | 0.4080 | 0.6029 | 0.4897 |
| 200 | 0.6049 | 0.8250 | 0.6038 | 0.6306 | 0.6043 | 0.7120 |

Since both CTs and VTs can introduce errors, an error analysis was conducted to study the impacts of measurement errors. In the analysis, an error of 2% for magnitude and 2° for angle are added to the voltages and currents measured at the line ends. Errors on fault location estimates are then investigated for various types of LG faults. Table 12 and Table 14 present the results for a 2% error in the magnitude of the voltage and current measurements at both ends of the line, respectively. Table 13 and Table 15 present the results for the 2° error in the angle of the voltage and the current measurements at both ends of the line, respectively. From Tables 12-15, it can be seen that measurement errors within the range specified above had almost or virtually no impact on the fault location accuracy.

TABLE 12
INFLUENCE OF 2% VOLTAGE MAGNITUDE
ERROR ON FAULT-LOCATION ESTIMATES
FOR SINGLE-LINE-TO-GROUND FAULTS

| Fault | Fault | Actual | Estimated | Error of |
|---|---|---|---|---|
| Type | Res. (Ω) | FL (p.u) | FL (p.u) | Estimated FL (%) |
| AG | 10 | 0.2 | 0.2007 | 0.3421 |
| | | 0.4 | 0.3990 | 0.2430 |
| | | 0.6 | 0.5974 | 0.4344 |
| | | 0.8 | 0.7958 | 0.5257 |
| | 100 | 0.2 | 0.2007 | 0.3411 |
| | | 0.4 | 0.3990 | 0.2433 |
| | | 0.6 | 0.5974 | 0.4345 |
| | | 0.8 | 0.7958 | 0.5256 |
| BG | 10 | 0.2 | 0.2007 | 0.3431 |
| | | 0.4 | 0.3990 | 0.2427 |
| | | 0.6 | 0.5974 | 0.4345 |
| | | 0.8 | 0.7958 | 0.5258 |
| | 100 | 0.2 | 0.2007 | 0.3511 |
| | | 0.4 | 0.3990 | 0.2413 |
| | | 0.6 | 0.5974 | 0.4353 |
| | | 0.8 | 0.7958 | 0.5280 |
| CG | 10 | 0.2 | 0.2007 | 0.3442 |
| | | 0.4 | 0.3990 | 0.2425 |
| | | 0.6 | 0.5974 | 0.4346 |
| | | 0.8 | 0.7958 | 0.5260 |
| | 100 | 0.2 | 0.2007 | 0.3608 |
| | | 0.4 | 0.3990 | 0.2397 |
| | | 0.6 | 0.5974 | 0.4364 |
| | | 0.8 | 0.7958 | 0.5302 |

TABLE 13
INFLUENCE OF 2° VOLTAGE ANGLE
ERROR ON FAULT-LOCATION ESTIMATES
FOR SINGLE-LINE-TO-GROUND FAULTS

| Fault | Fault | Actual | Estimated | Error of |
|---|---|---|---|---|
| Type | Res. (Ω) | FL (p.u) | FL (p.u) | Estimated FL (%) |
| AG | 10 | 0.2 | 0.2007 | 0.3429 |
| | | 0.4 | 0.3990 | 0.2428 |
| | | 0.6 | 0.5974 | 0.4345 |
| | | 0.8 | 0.7958 | 0.5260 |
| | 100 | 0.2 | 0.2007 | 0.3419 |
| | | 0.4 | 0.3990 | 0.2430 |
| | | 0.6 | 0.5974 | 0.4345 |
| | | 0.8 | 0.7958 | 0.5259 |
| BG | 10 | 0.2 | 0.2007 | 0.3439 |
| | | 0.4 | 0.3990 | 0.2425 |
| | | 0.6 | 0.5974 | 0.4345 |
| | | 0.8 | 0.7958 | 0.5261 |
| | 100 | 0.2 | 0.2007 | 0.3519 |
| | | 0.4 | 0.3990 | 0.2411 |
| | | 0.6 | 0.5974 | 0.4354 |
| | | 0.8 | 0.7958 | 0.5283 |
| CG | 10 | 0.2 | 0.2007 | 0.3450 |
| | | 0.4 | 0.3990 | 0.2422 |
| | | 0.6 | 0.5974 | 0.4346 |
| | | 0.8 | 0.7958 | 0.5263 |
| | 100 | 0.2 | 0.2007 | 0.3616 |
| | | 0.4 | 0.3990 | 0.2395 |
| | | 0.6 | 0.5974 | 0.4365 |
| | | 0.8 | 0.7958 | 0.5305 |

TABLE 14
INFLUENCE OF 2% CURRENT MAGNITUDE
ERROR ON FAULT-LOCATION ESTIMATES
FOR SINGLE-LINE-TO-GROUND FAULTS

| Fault | Fault | Actual | Estimated | Error of |
|---|---|---|---|---|
| Type | Res. (Ω) | FL (p.u) | FL (p.u) | Estimated FL (%) |
| AG | 10 | 0.2 | 0.2007 | 0.3438 |
| | | 0.4 | 0.3990 | 0.2425 |
| | | 0.6 | 0.5974 | 0.4345 |
| | | 0.8 | 0.7958 | 0.5262 |
| | 100 | 0.2 | 0.2007 | 0.3428 |
| | | 0.4 | 0.3990 | 0.2428 |
| | | 0.6 | 0.5974 | 0.4346 |
| | | 0.8 | 0.7958 | 0.5262 |
| BG | 10 | 0.2 | 0.2007 | 0.3448 |
| | | 0.4 | 0.3990 | 0.2422 |
| | | 0.6 | 0.5974 | 0.4346 |
| | | 0.8 | 0.7958 | 0.5263 |
| | 100 | 0.2 | 0.2007 | 0.3528 |
| | | 0.4 | 0.3990 | 0.2408 |
| | | 0.6 | 0.5974 | 0.4354 |
| | | 0.8 | 0.7958 | 0.5285 |
| CG | 10 | 0.2 | 0.2007 | 0.3459 |
| | | 0.4 | 0.3990 | 0.2420 |
| | | 0.6 | 0.5974 | 0.4347 |
| | | 0.8 | 0.7958 | 0.5266 |
| | 100 | 0.2 | 0.2007 | 0.3625 |
| | | 0.4 | 0.3990 | 0.2392 |
| | | 0.6 | 0.5974 | 0.4365 |
| | | 0.8 | 0.7958 | 0.5308 |

TABLE 15
INFLUENCE OF 2° CURRENT ANGLE
ERROR ON FAULT-LOCATION ESTIMATES
FOR SINGLE-LINE-TO-GROUND FAULTS

| Fault | Fault | Actual | Estimated | Error of |
|---|---|---|---|---|
| Type | Res. (Ω) | FL (p.u) | FL (p.u) | Estimated FL (%) |
| AG | 10 | 0.2 | 0.2007 | 0.3430 |
| | | 0.4 | 0.3990 | 0.2427 |
| | | 0.6 | 0.5974 | 0.4344 |
| | | 0.8 | 0.7958 | 0.5259 |
| | 100 | 0.2 | 0.2007 | 0.3420 |
| | | 0.4 | 0.3990 | 0.2430 |
| | | 0.6 | 0.5974 | 0.4345 |
| | | 0.8 | 0.7958 | 0.5259 |
| BG | 10 | 0.2 | 0.2007 | 0.3440 |
| | | 0.4 | 0.3990 | 0.2424 |
| | | 0.6 | 0.5974 | 0.4345 |
| | | 0.8 | 0.7958 | 0.5261 |
| | 100 | 0.2 | 0.2007 | 0.3521 |
| | | 0.4 | 0.3990 | 0.2410 |
| | | 0.6 | 0.5974 | 0.4354 |
| | | 0.8 | 0.7958 | 0.5282 |
| CG | 10 | 0.2 | 0.2007 | 0.3452 |
| | | 0.4 | 0.3990 | 0.2422 |
| | | 0.6 | 0.5974 | 0.4346 |
| | | 0.8 | 0.7958 | 0.5263 |
| | 100 | 0.2 | 0.2007 | 0.3617 |
| | | 0.4 | 0.3990 | 0.2394 |
| | | 0.6 | 0.5974 | 0.4364 |
| | | 0.8 | 0.7958 | 0.5305 |

Embodiments of methods for adaptive fault location in power system networks using synchronized pre-fault and post-fault measurements obtained by PMUs are capable of locating faults with a relatively very high accuracy. Also, embodiments of methods for adaptive fault location in power system networks can be implemented typically without requiring data for the power system network to be provided by the electric utility. Moreover, line parameters and a power system's Thevenin's equivalents at two nodes of a faulty line are determined online using PMU measurements. This can facilitate reducing degradation of system impedance and line parameter uncertainty. Additionally, fault-type selection typically is not required. Also, accuracy of the adaptive fault location determination is relatively independent of fault type, fault location, fault resistance, fault inception angle and pre-fault loading, for example. Further, adaptive fault location using embodiments of methods for adaptive fault location in power system networks is relatively not sensitive to measurement errors.

It is to be understood that the present invention is not limited to the embodiments described above, but encompasses any and all embodiments within the scope of the following claims.

We claim:

1. A method for adaptive fault location in a power system network, comprising the steps of:
acquiring a plurality of independent sets of phasor measurement unit (PMU) pre-fault measurements from a first terminal and a second terminal of a line in a power system network;
acquiring at least one set of PMU post-fault measurements from the first terminal and from the second terminal;
determining the power system network Thevenin equivalents at the first terminal and at the second terminal based on the pre-fault measurements;
determining line parameters based on the pre-fault measurements using multiple measurements with linear regression;
extracting superimposed electrical measurements using the determined line parameters based on a most recent set of the pre-fault measurements and the post-fault measurements;
performing a symmetrical transformation of the superimposed electrical measurements to correspond to a sequence network;
determining a sequence source impedance for the first terminal and a sequence source impedance for the second terminal based on the transformed electrical measurements;
determining a sequence voltage at the first terminal as a first fault voltage and a sequence voltage at the second terminal as a second fault voltage based on the corresponding determined sequence source impedances and the transformed electrical measurements; and
plotting the magnitudes of the determined first fault voltage and second fault voltage along the length of a transmission line between the first terminal and second terminal, wherein a point of intersection between the plotted first fault voltage and the plotted second fault voltage determines the fault distance between at least one of the first terminal and the second terminal and a fault point corresponding to a fault location.

2. The method for adaptive fault location in a power system network according to claim 1, further comprising the step of locating a single line to ground (LG) fault type using the determined first and second fault voltages.

3. The method for adaptive fault location in a power system network according to claim 1, further comprising the step of locating a line to line (LL) fault type using the determined first and second fault voltages.

4. The method for adaptive fault location in a power system network according to claim 1, further comprising the step of locating a line to line to ground (LLG) fault type using the determined first and second fault voltages.

5. The method for adaptive fault location in a power system network according to claim 1, further comprising the step of locating a three phase (LLL) fault type using the determined first and second fault voltages.

6. The method for adaptive fault location in a power system network according to claim 1, wherein said pre-fault and post-fault phasor measurement acquisition steps comprise obtaining said phasor measurements from Phasor Measurement Units (PMUs) in operable communication with said first and second terminals of said power system network.

7. The method for adaptive fault location in a power system network according to claim 6, further comprising the step of using synchronization signals from satellite transmissions of a global positioning system (GPS) to synchronize said acquisition of the pre-fault and the post-fault phasor measurements.

8. The method for adaptive fault location in a power system network according to claim 1, further comprising the step of using synchronization signals from satellite transmissions of a global positioning system (GPS) to synchronize said acquisition of the pre-fault and the post-fault phasor measurements.

9. A method for adaptive fault location in a power system network, comprising the steps of:
acquiring three independent sets of pre-fault voltage and current (V_{A}, I_{A}) phasor measurements from a first terminal of said power system network;
acquiring three independent sets of pre-fault voltage and current (V_{B}, I_{B}) phasor measurements from a second terminal of said power system network;
determining said power system network's Thevenin equivalent at said first terminal from said first terminal pre-fault phasor measurements;
determining said power system network's Thevenin equivalent at said second terminal from said second terminal pre-fault phasor measurements;
calculating line parameters based on the pre-fault measurements using multiple measurements with linear regression;
acquiring a first terminal post-fault voltage and current (V_{A}, I_{A}) phasor measurement from said first terminal of said power system network;
acquiring a second terminal post-fault voltage and current (V_{B}, phasor measurement from said second terminal of said power system network;
extracting superimposed electrical measurements based on a most recent set of said pre-fault measurements and said post-fault measurements, said superimposed electrical measurements being transformed to correspond to a sequence network, where: ΔV_{Ai} is an i^{th} sequence of superimposed voltage at said first terminal; ΔV_{Bi} is an i^{th} sequence of superimposed voltage at said second terminal; ΔI_{Ai} is an i^{th} sequence of superimposed current at said first terminal; ΔI_{Bi} is an i^{th} sequence of superimposed current at said second terminal; Zᵢ is an i^{th} sequence impedance of the line between said first and second terminals; Yᵢ is an i^{th} sequence admittance of the line between said first and second terminals; R_{f} is a fault resistance; I_{fi} is an i^{th} sequence of fault current; Z_{ASi} is an i^{th} sequence of equivalent source impedance at said first terminal; Z_{BSi} is an i^{th} sequence of equivalent source impedance at said second terminal; L is a length parameter of a total length of a transmission line between the first terminal and the second terminal; and D is a distance parameter of a distance between at least one said corresponding first terminal or said corresponding second terminal and a fault point F as a fault location;
determining a first fault voltage originating from said first terminal (V_{AFi}) as characterized by the relation:
$${V}_{AFi} = ( Δ {I}_{Ai} - Δ {V}_{Ai} {DY}_{i} ) \times ( ( {Z}_{ASi} ‖ \frac{1}{{DY}_{i}} ) + {DZ}_{i} ) , \\ where \\ {Z}_{ASi} = \frac{Δ {V}_{Ai}}{Δ {I}_{Ai}} ,$$
determining a second fault voltage originating from said second terminal (V_{BFi}) as characterized by the relation:
$${V}_{BFi} = ( Δ {I}_{Bi} - Δ {V}_{Bi} ( L - D ) {Y}_{i} ) \times ( ( {Z}_{BSi} ‖ \frac{1}{( L - D ) {Y}_{i}} ) + ( L + D ) {Z}_{i} ) , \\ where \\ {Z}_{BSi} = \frac{Δ {V}_{Bi}}{Δ {I}_{Bi}} ; \\ and$$
determining a point of intersection between a plot of the first fault voltage magnitude |V_{AFi}| and a plot of the second fault voltage magnitude |V_{BFi}| along an entire length of said line L, wherein said point of intersection is the fault location.

10. The method for adaptive fault location in a power system network according to claim 9, further comprising the step of locating a single line to ground (LG) fault type using the determined first and second fault voltages.

11. The method for adaptive fault location in a power system network according to claim 9, further comprising the step of locating a line to line (LL) fault type using the determined first and second fault voltages.

12. The method for adaptive fault location in a power system network according to claim 9, further comprising the step of locating a line to line to ground (LLG) fault type using the determined first and second fault voltages.

13. The method for adaptive fault location in a power system network according to claim 9, further comprising the step of locating a three phase (LLL) fault type using the determined first and second fault voltages.

14. The method for adaptive fault location in a power system network according to claim 9, wherein said pre-fault and post-fault phasor measurement acquisition steps comprise obtaining said phasor measurements from Phasor Measurement Units (PMUs) in operable communication with said first and second terminals of said power system network.

15. The method for adaptive fault location in a power system network according to claim 14, further comprising the step of using synchronization signals from satellite transmissions of a global positioning system (GPS) to synchronize said acquisition of the pre-fault and the post-fault phasor measurements.

16. The method for adaptive fault location in a power system network according to claim 9, further comprising the step of using synchronization signals from satellite transmissions of a global positioning system (GPS) to synchronize said acquisition of the pre-fault and the post-fault phasor measurements.
